(19) United States
(12) Patent Application Publication
(10) Pub. No.: US 2004/0041660 A1
(43) Pub. Date: Mar. 4, 2004

(54) Laminated dielectric filter, and antenna duplexer and communication equipment using the same

(76) Inventors: Emiko Kawahara, Osaka (JP); Toru Yamada, Osaka (JP); Hiroshi Kushitani, Osaka (JP); Hideaki Nakakubo, Souraku-gun (JP)

Correspondence Address: ROSENTHAL & OSHA L.L.P., Suite 2800, 1221 McKinney St., Houston, TX, 77010, US

(21) Appl. No.: 10/655,098

(22) Filed: Sep. 4, 2003

Related U.S. Application Data
(63) Continuation of application No. 09/631,744, filed on Aug. 4, 2000.

(30) Foreign Application Priority Data
Aug. 5, 1999 (JP) 11-222839

(51) Int. Cl. H03H 9/00

(52) U.S. Cl. 333/133

(57) ABSTRACT

A laminated dielectric filter is formed by coupling a plurality of resonators to one another by electromagnetic-field coupling. In the laminated dielectric filter, a bypass circuit formed of a series circuit including bypass capacitors and transmission lines is provided in parallel to a magnetic-field bypass coupling between non-adjacent resonators. Thus, capacitance of the bypass capacitors can be regulated without being affected by the magnetic-field bypass coupling between the non-adjacent resonators. As a result, attenuation poles outside a passband can be controlled freely.

### FIELD OF THE INVENTION

The present invention relates to a filter, particularly a laminated dielectric filter, which mainly is used in high-frequency radio equipment such as portable telephones.

### BACKGROUND OF THE INVENTION

Recently, with reduction in size of communication equipment, laminated dielectric filters effective for size reduction are used commonly as high-frequency filters. One example of conventional laminated dielectric filters is described with reference to drawings as follows.

FIG. 4 shows an exploded perspective view of a conventional laminated dielectric filter. The conventional laminated dielectric filter shown in FIG. 4 includes dielectric layers 301, shield electrodes 302a and 302b, resonator electrodes 303a, 303b, and 303c, capacitor electrodes 304a, 304b, 305a, 305b, 307a, 307b, and 307c, and side electrodes 308a, 308b, 308c, 308d, 309a, and 309b. In the dielectric layers 301, the shield electrode 302a, the resonator electrodes 303a, 303b, and 303c, the capacitor electrodes 304a, 304b, 305a, 305b, 307a, 307b, and 307c, and the shield electrode 302b are positioned sequentially. In addition, the side electrodes 308a and 308b on the left and right side faces of the dielectric body connect the shield electrodes 302a and 302b to form ground terminals. The side electrode 308c on the back face of the dielectric body connects the shield electrodes 302a and 302b and a common short-circuit end of the resonator electrodes 303a, 303b, and 303c to form a ground terminal. The side electrodes 308d on the front face of the dielectric body connect the capacitor electrodes 307a, 307b, and 307c corresponding to the open ends of the resonator electrodes 303a, 303b, and 303c, respectively. The side electrodes 309a and 309b on the left and right side faces of the dielectric body are connected to the capacitor electrodes 304a and 304b to form input/output terminals.

The structural view of the laminated dielectric filter thus configured is shown in FIGS. 5A and 5B. FIG. 5A is its left side view and FIG. 5B its front view. FIGS. 5A and 5B also show schematic capacitors formed between electrodes formed on an upper surface of a dielectric layer and electrodes formed on an upper surface of another dielectric layer, which oppose each other, respectively.

An equivalent circuit of the conventional laminated dielectric filter shown in FIGS. 4, 5A and 5B can be illustrated as shown in FIG. 6. The resonator electrodes 303a, 303b, and 303c form front end short-circuit ¼ wavelength resonators R303a, R303b, and R303c as shown in FIG. 6. The open ends of the resonators R303a, R303b, and R303c are connected to the ground terminals via the loading capacitor elements C307a, C307b, and C307c, respectively. The open ends of the resonators R303a and R303b are connected to each other via an inter-stage coupling capacitor element C305a and the open ends of the resonators R303b and R303c via an inter-stage coupling capacitor element C305b. Furthermore, the resonators R303a and R303c on the outer sides are connected to the input/output terminals via input/output coupling capacitor elements C304a and C304b, respectively.

Therefore, the laminated dielectric filter shown in FIG. 4 functions as a bandpass filter with the one ends of the capacitor elements C304a and C304b serving as the input/output ends. In addition, two attenuation poles are formed by a parallel resonance circuit formed of the inter-stage coupling capacitors C305a and C305b and magnetic-field couplings 401a and 401b occurring between the resonators R303a and R303b and between the resonators R303b and R303c. The frequencies of the attenuation poles depend on inter-stage coupling capacitance and the magnitude of the magnetic-field couplings, i.e. resonant gaps.

In the configuration as described above, however, the resonators R303a and R303c on the both sides bypass the resonator R303b positioned at the center to be coupled directly to each other by a magnetic-field coupling as indicated with the numeral 401c. Therefore, frequency characteristics of the two attenuation poles vary and thus the characteristics as designed cannot be obtained. The magnetic-field coupling 401c is determined uniquely when the magnetic-field couplings 401a and 401b are determined, i.e. when the resonant gaps are determined. Consequently, the two attenuation poles cannot be controlled freely while consideration is given to the magnetic-field coupling 401c.

### SUMMARY OF THE INVENTION

The present invention is intended to provide a filter, particularly a laminated dielectric filter, allowing attenuation poles outside a passband to be controlled freely.

In one embodiment, a filter of the present invention includes a plurality of resonators coupled to one another by electromagnetic-field coupling. In the embodiment, non-adjacent resonators are electrically coupled to each other with a series circuit formed of a capacitor and a transmission line.

According to the filter of this embodiment, the capacitor formed between the non-adjacent resonators is regulated without being affected by the magnetic-field bypass coupling between the non-adjacent resonators. Thus, attenuation poles outside a passband can be controlled freely.

In the above-mentioned filter, it is preferred to electrically couple adjacent resonators to each other with a series circuit of a capacitor and a transmission line.

According to this configuration, it is possible to control at least two attenuation poles of a parallel resonance circuit formed by the electromagnetic coupling and capacitive coupling between adjacent resonators.

In the above-mentioned filter, it is preferable that the plurality of resonators and the transmission line are formed inside a dielectric body.

According to this configuration, the capacitor as a component of the filter can be formed easily by using the plurality of resonators and the transmission line as electrodes.

In another embodiment, a dielectric filter of the present invention includes a plurality of shield electrodes formed on outer faces of a dielectric body, resonator electrodes formed of at least three front end short-circuit ¼ wavelength transmission lines, a plurality of first transmission line electrodes, each of which has portions opposing respective portions of two adjacent resonator electrodes included in the resonator electrodes, and second transmission line electrodes having portions opposing the plurality of first transmission electrodes, respectively. The resonator electrodes, the first transmission line electrodes, and the second transmission line electrodes are formed between the plurality of shield electrodes.

In some embodiments, inter-stage coupling capacitors are formed between adjacent resonator electrodes and the first transmission line electrodes opposing them, and bypass capacitors are formed between the first transmission line electrodes and the second transmission line electrodes opposing them. Due to the bypass circuit formed of a series circuit including the bypass capacitors and the second transmission line electrodes, the attenuation poles outside the passband can be controlled freely by the adjustment of capacitance of the inter-stage coupling capacitors without being affected by a magnetic-field bypass coupling between non-adjacent resonator electrodes. Thus, a capacitive coupling type bandpass filter having the above-mentioned effect of controlling the attenuation freely can be obtained.

In the dielectric filter, it is preferable that the plurality of shield electrodes are connected to one another, and then are grounded.

According to this configuration, between the shield electrodes thus grounded, filter components can be positioned. Therefore, without being affected by an external electromagnetic field, desired filter characteristics can be obtained as designed.

In another embodiment, a laminated dielectric filter of the present invention has the following configuration. A first dielectric layer is laminated above a first shield electrode. On the upper surface of the first dielectric layer, resonator electrodes formed of at least three front end short-circuit ¼ wavelength transmission lines are formed. Above the resonator electrodes, a second dielectric layer is laminated. On the upper surface of the second dielectric layer, a plurality of inter-stage coupling capacitor electrodes are formed. Each of the inter-stage coupling capacitor electrodes is formed of a transmission line having portions opposing respective portions of two adjacent resonator electrodes included in the resonator electrodes. Above the inter-stage coupling capacitor electrodes, a third dielectric layer is laminated. On the upper surface of the third dielectric layer, bypass electrodes are formed. The bypass electrodes are formed of transmission lines having portions opposing the plurality of inter-stage coupling capacitor electrodes, respectively. Above the bypass electrodes, a fourth dielectric layer is laminated. On the upper surface of the fourth dielectric layer, a second shield electrode is positioned.

In some embodiments, inter-stage coupling capacitors are formed between adjacent resonator electrodes on the first dielectric layer and the inter-stage coupling capacitor electrodes on the second dielectric layer opposing the adjacent resonator electrodes. Bypass capacitors are formed between the inter-stage coupling capacitor electrodes on the second dielectric layer and the bypass electrodes on the third dielectric layer opposing them. Due to the bypass circuit of a series circuit including the bypass capacitors and the bypass electrodes, attenuation poles outside a passband can be controlled freely by the adjustment of capacitance of the inter-stage coupling capacitors without being affected by a magnetic-field bypass coupling between non-adjacent resonator electrodes. Thus, a capacitive coupling type bandpass filter having the above-mentioned effect of controlling the attenuation poles freely can be obtained.

In the above-mentioned laminated dielectric filter of the present invention, it is preferable that the first shield electrode is provided on the upper surface of a fifth dielectric layer.

In the above-mentioned laminated dielectric filter of the present invention, it is preferred to laminate a sixth dielectric layer above the second shield electrode.

According to this configuration, the sixth dielectric layer can protect the second shield electrode. In addition, it also is possible to form the same resonator electrodes as those on the first dielectric layer on the upper surface of the six dielectric layer and further laminate the same dielectric layers as the second and third dielectric layers, on the upper surfaces of which the inter-stage coupling capacitor electrodes and the bypass electrodes are formed, respectively, thus obtaining filters separated by the second shield electrode from each other.

In the above-mentioned laminated dielectric filter of the present invention, it is preferable that the first and second shield electrodes are connected to each other and then are grounded.

According to this configuration, filter components can be positioned between the first and second shield electrodes that are grounded. Therefore, desired filter characteristics can be obtained as designed without being affected by the external electromagnetic field.

In the above-mentioned dielectric filter or laminated dielectric filter of the present invention, it is preferred to include capacitor electrodes formed of the transmission lines opposing the resonator electrodes on the outermost sides and connect the capacitor electrodes to the side electrodes to form input/output terminals.

In the above-mentioned dielectric filter or laminated dielectric filter of the present invention, it is preferable that the capacitor electrodes are formed of the transmission lines opposing open ends of the resonator electrodes and are grounded.

According to this configuration, between the open ends of the resonator electrodes and the capacitor electrodes opposing them, loading capacitors as components of the bandpass filter can be formed.

Further, it is preferred to use the filter, dielectric filter, or laminated dielectric filter of the present invention in an antenna duplexer as one of or both of filters on transmission and reception sides.

According to this configuration, a conventional coaxial resonator with a high space factor, which has been used in an antenna duplexer, can be omitted. Therefore, the size of the antenna duplexer can be reduced considerably.

It also is preferred to use the filter, dielectric filter, or laminated dielectric filter of the present invention in communication equipment.

According to the various embodiments of the invention, desired characteristics can be obtained in communication equipment of limited size. Thus, the filter, dielectric filter, or laminated dielectric filter of the present invention also may contribute to the size reduction of the communication equipment.

### BRIEF DESCRIPTION OF THE DRAWINGS

FIG. 1 is an exploded perspective view showing a structural example of a laminated dielectric filter according to an embodiment of the present invention.

FIG. 2A is a schematic left side view showing the configuration of the laminated dielectric filter according to the present embodiment.

FIG. 2B is a schematic front view showing the configuration of the laminated dielectric filter according to the present embodiment.

FIG. 3 is a schematic diagram of an equivalent circuit of the laminated dielectric filter according to the present embodiment.

FIG. 4 is an exploded perspective view of a conventional laminated dielectric filter.

FIG. 5A is a schematic left side view showing the configuration of the conventional laminated dielectric filter.

FIG. 5B is a schematic front view showing the configuration of the conventional laminated dielectric filter.

FIG. 6 is a schematic diagram of an equivalent circuit of the conventional laminated dielectric filter.

FIG. 7 is a graph showing transmission characteristics of the laminated dielectric filter according to the present invention and the conventional laminated dielectric filter.

FIG. 8 is a block diagram of an antenna duplexer using a laminated dielectric filter according to the present embodiment.

FIG. 9 is a block diagram of communication equipment using a laminated dielectric filter according to the present embodiment.

### DETAILED DESCRIPTION OF THE INVENTION

A laminated dielectric filter according to the present invention is described with reference to the drawings as follows.

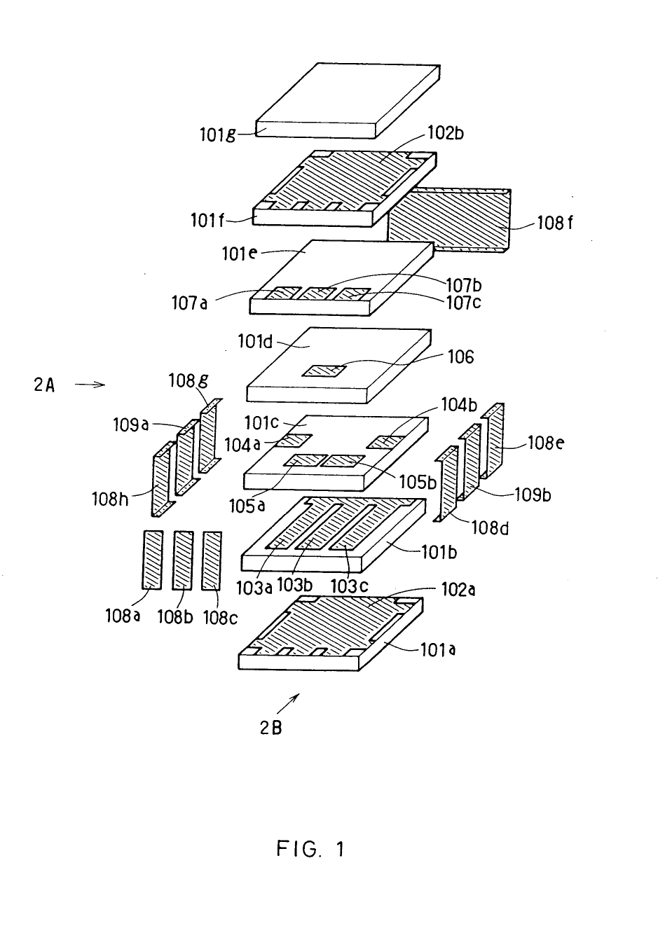

FIG. 1 is an exploded perspective view of a laminated dielectric filter according to an embodiment of the present invention. In FIG. 1, numerals 101a, 101b, 101c, 101d, 101e, 101f, and 101g indicate dielectric layers, numerals 102a and 102b shield electrodes, numerals 103a, 103b, and 103c resonator electrodes, numerals 104a, 104b, 105a, 105b, 106, 107a, 107b, and 107c capacitor electrodes, and numerals 108a, 108b, 108c, 108d, 108e, 108f, 108g, 108h, 109a, and 109b side electrodes. The following description is directed to the laminated structure of this laminated dielectric filter. On a first dielectric layer 101a, a first shield electrode 102a is positioned, and above the electrode 102a, a second dielectric layer 101b is laminated. On the upper surface of the dielectric layer 101b, three resonator electrodes 103a, 103b, and 103c are positioned, above which a third dielectric layer 101c is laminated. On the upper surface of the dielectric layer 101c, four capacitor electrodes 104a, 104b, 105a, and 105b are positioned. Above those capacitor electrodes, a fourth dielectric layer 101d is laminated. On the upper surface of the dielectric layer 101d, a capacitor electrode 106 is positioned, and above the capacitor electrode 106, a fifth dielectric layer 101e is laminated. On the upper surface of the dielectric layer 101e, three capacitor electrodes 107a, 107b, and 107c are positioned. Furthermore, above these capacitor electrodes, a sixth dielectric layer 101f is laminated. On the upper surface of the dielectric layer 101f, a second shield electrode 102b is positioned, and above the electrode 102b, a seventh dielectric layer 101g is laminated, thus forming the laminated structure of the dielectric filters.

On the front face of the dielectric body with the above-mentioned laminated structure, the side electrodes 108a, 108b, and 108c are provided, and on the side faces of the dielectric body; the side electrodes 108d 108e, 108g, and 108h are provided. In addition, the side electrode 108f is provided on the back face of the dielectric body, and the side electrodes 109a and 109b are provided on the side faces of the dielectric body. The connections between these side electrodes and electrodes formed on the respective dielectric layers are described as follows.

The first shield electrode 102a, a short-circuit end on the back face side of the dielectric body at which the resonator electrodes 103a, 103b, and 103c are connected to one another, and the second shield electrode 102b are connected with the side electrode 108f, and then are grounded. The capacitor electrode 104a and the side electrode 109a are connected to each other and the capacitor electrode 104b and the side electrode 109b also are connected to each other. The first shield electrode 102a, the capacitor electrodes 107a, 107b, and 107c, and the second shield electrode 102b are connected with the side electrodes 108a, 108b, and 108c, and then are grounded. The first shield electrode 102a and the second shield electrode 102b are connected to each other with the side electrodes 108d, 108e, 108g, and 108h. Furthermore, the side electrodes 108a, 108c, and 108e and 108g are connected to the side electrodes 108h, 108d, and 108f, respectively.

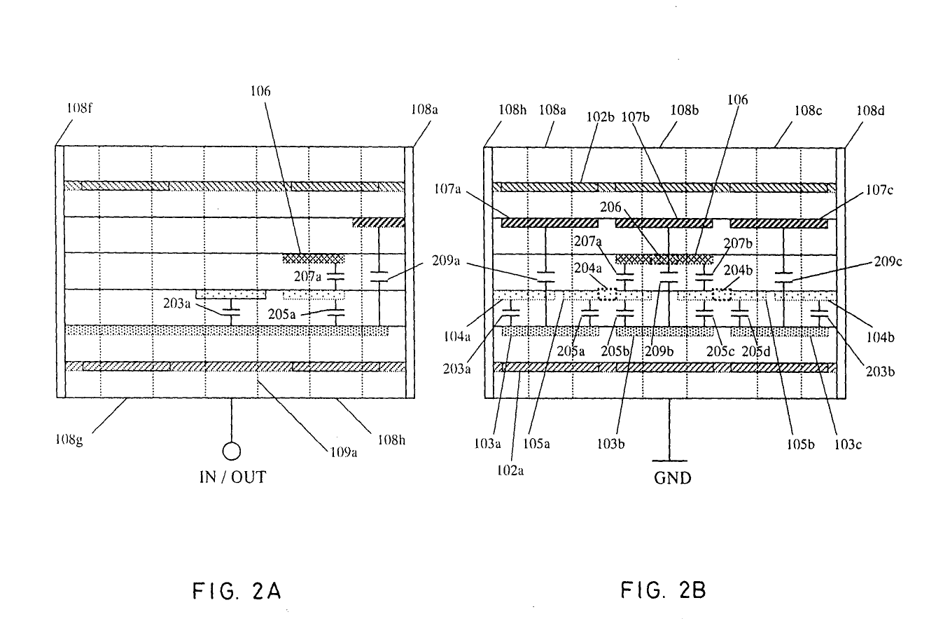

The structural view of the laminated dielectric filter with the above-mentioned configuration is shown in FIGS. 2A and 2B. FIG. 2A is its left side view and FIG. 2B is its front view. FIGS. 2A and 2B also show capacitors schematically. The capacitors are formed between electrodes formed on an upper surface of a dielectric layer and electrodes formed on an upper surface of another dielectric layer, which oppose to one another.

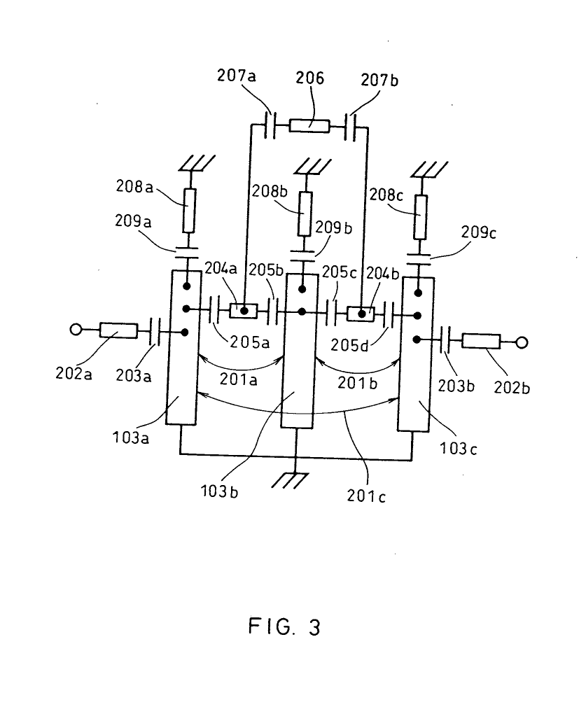

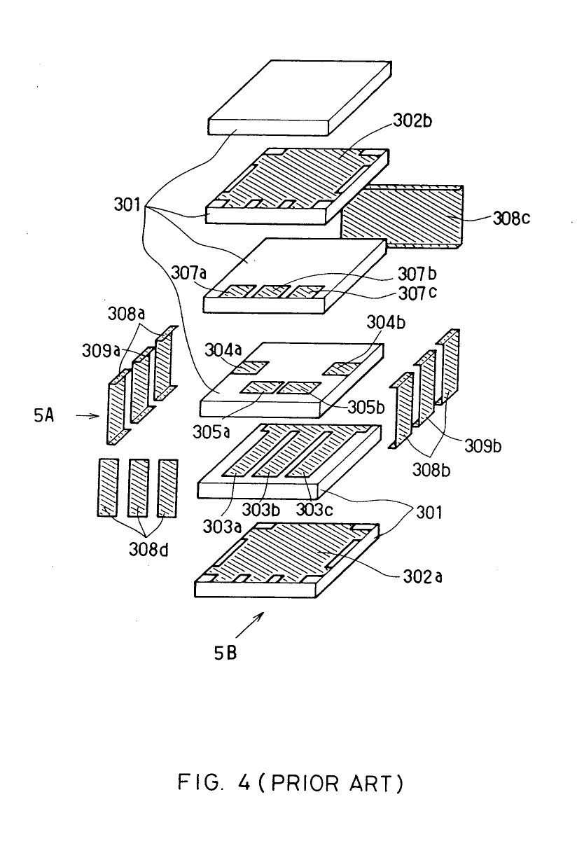

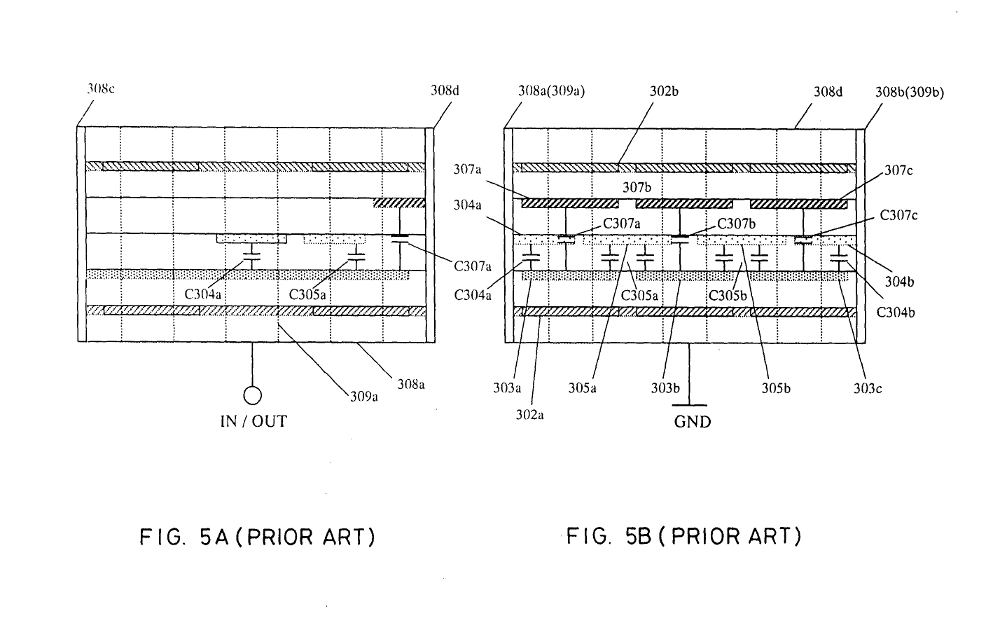

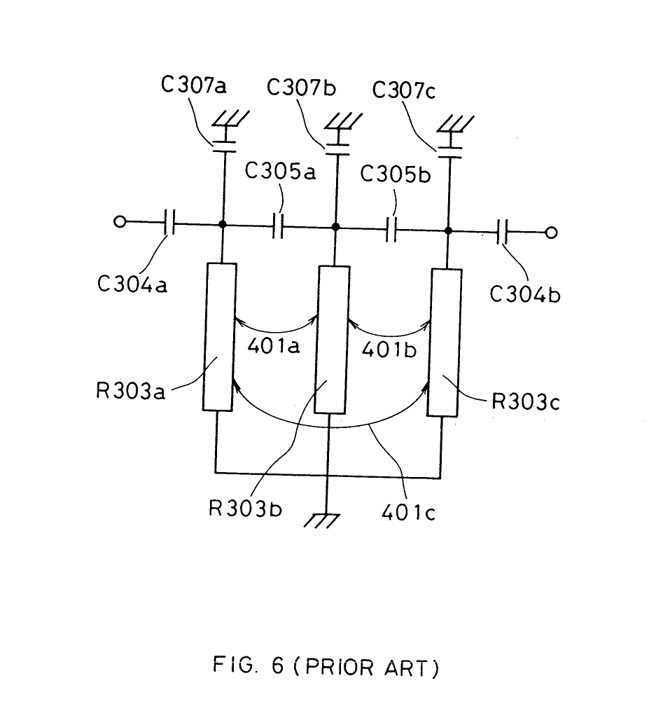

An equivalent circuit of the laminated dielectric filter of the present invention shown in FIGS. 1, 2A, and 2B can be illustrated as in FIG. 3. In FIG. 3, portions corresponding to those in FIGS. 1, 2A, and 2B are indicated with the same numerals as in FIGS. 1, 2A, and 2B. The capacitors formed of opposed electrodes in FIGS. 1, 2A, and 2B are expressed in combination of capacitors and transmission lines while consideration also is given to the lengths of the electrodes. The operation of the laminated dielectric filter according to the present invention is described with reference to the structural views shown in FIGS. 2A and 2B and the equivalent circuit shown in FIG. 3 as follows.

The resonator electrodes 103a, 103b, and 103c are grounded via the side electrode 108f and therefore function as ¼ wavelength resonators. The capacitor electrodes 107a, 107b, and 107c are arranged opposing open ends of the resonator electrodes 103a, 103b, and 103c to form loading capacitors 209a, 209b, and 209c for regulating resonance frequencies of the resonators. The loading capacitors 209a, 209b, and 209c are grounded via transmission lines 208a, 208a, and 208c corresponding to the side electrodes 108a, 108b, and 108c.

The capacitor electrode 105a is arranged opposing a part of the resonator electrode 103a and a part of the resonator electrode 103b, thus forming capacitors 205a and 205b functioning as inter-stage coupling capacitors. The capacitors 205a and 205b are connected with transmission line 204a corresponding to the portion, which does not oppose the resonator electrodes 103a and 103b, of the capacitor electrode 105a.

Similarly, the capacitor electrode 105b is arranged opposing a part of the resonator electrode 103b and a part of the resonator electrode 103c, thus forming inter-stage coupling capacitors 205c and 205d. The capacitors 205c and 205d are connected with transmission line 204b corresponding to the portion, which does not oppose the resonator electrodes 103b and 103c, of the capacitor electrode 105b.

A bypass electrode 106 is positioned opposing the capacitor electrodes 105a and 105b to form bypass capacitors 207a and 207b. These bypass capacitors 207a and 207b are connected with a transmission line 206 corresponding to the portion, which does not oppose the capacitor electrodes 105a and 105b, of the bypass electrode 106, which functions as a bypass circuit parallel to a magnetic-field bypass coupling 201c between the resonator electrodes 103a and 103c.

The capacitor electrode 104a is positioned opposing a part of the resonator electrode 103a and the capacitor electrode 104b is positioned opposing a part of the resonator electrode 103c, thus forming input/output coupling capacitors 203a and 203b. These capacitors 203a and 203b are connected to the transmission lines 202a and 202b corresponding to the side electrodes 109a and 109b.

The resonance frequencies of a parallel resonance circuit formed of the bypass circuit and the magnetic-field bypass coupling 201c are set to be in the vicinities of the resonance frequencies of two attenuation poles formed by a parallel resonance circuit. The parallel resonance circuit is formed of magnetic-field couplings 201a and 201b occurring between the resonator electrodes 103a and 103b and between the resonator electrodes 103b an 103c, respectively, and the corresponding inter-stage coupling capacitors 205a and 205b and inter-stage coupling capacitors 205c and 205d, respectively. Thus, the impedance of the bypass circuit between the resonator electrodes 103a and 103c can be infinite in the vicinities of the resonance frequencies of the attenuation poles. Therefore, by providing the bypass circuit indicated as a series circuit formed of the transmission lines and capacitor elements, the attenuation poles outside the passband can be controlled freely by the adjustment of capacitance of the inter-stage coupling capacitors without being affected by the magnetic-field bypass coupling. Thus, a capacitive coupling type bandpass filter having the above-mentioned effect of controlling the attenuation poles freely can be obtained.

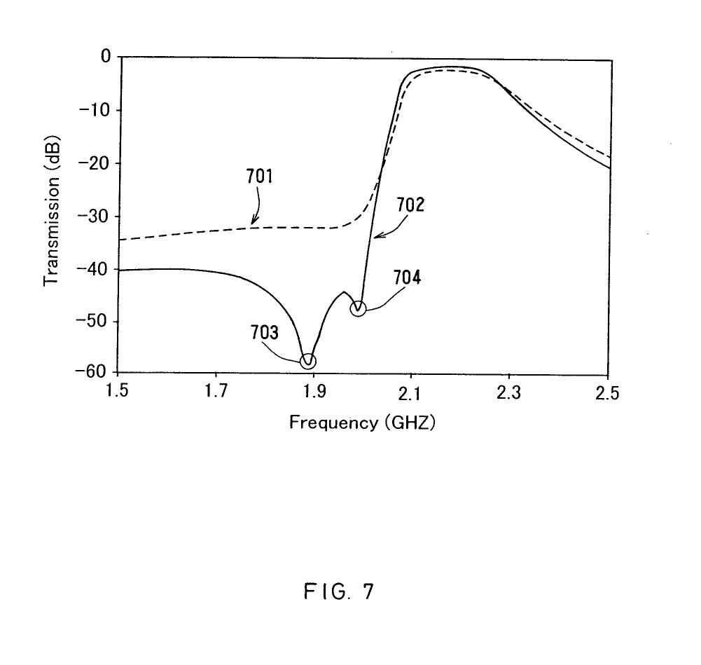

FIG. 7 shows experimental results indicating the above-mentioned effect and illustrating the transmission characteristics of the conventional example and of the present embodiment. In FIG. 7, the attenuation amounts outside the passband in the conventional example and the present embodiment are compared. Numeral 701 indicates the transmission characteristics of the conventional laminated dielectric filter. On the other hand, numeral 702 indicates the transmission characteristics of the laminated dielectric filter according to an embodiment of the present embodiment. It can be seen that steep and high attenuation characteristics can be obtained due to the control of the two attenuation poles 703 and 704.

As described above, according to the present embodiment, the bypass circuit formed of a series circuit including capacitor elements and transmission lines is provided in parallel to the magnetic-field bypass coupling, which enables the attenuation poles outside the passband to be controlled freely. Thus, a bandpass filter with steep attenuation characteristics as designed can be obtained.

In the present embodiment, a bandpass filter including the three-stage magnetic-field bypass coupling was described. However, the same effect also can be obtained in a filter having a configuration in which the bypass between the input and output terminals are achieved by using four stages or more or two stages.

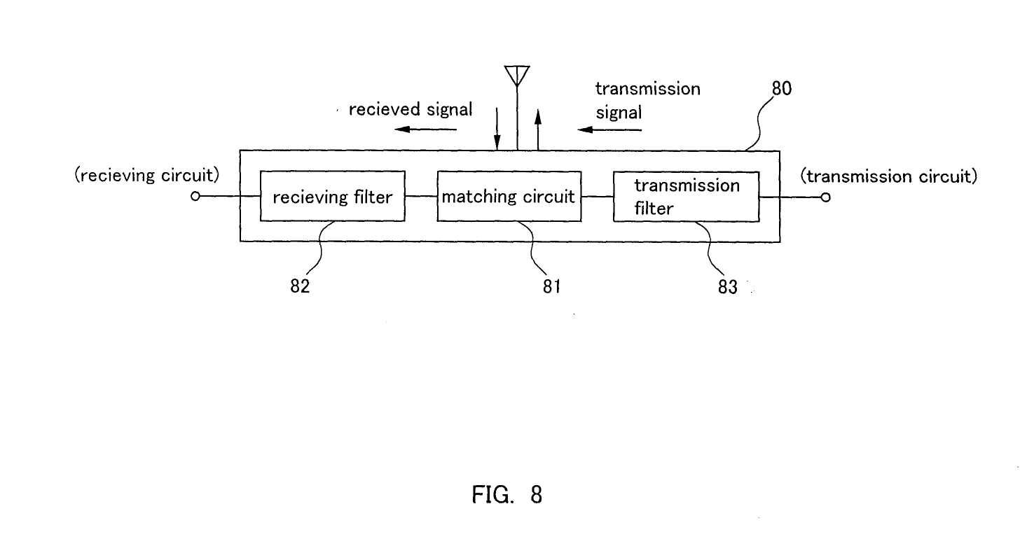

In addition, as shown in FIG. 8, when the laminated dielectric filter of the present embodiment is placed at each end of a matching circuit 81 connected to an antenna as a receiving filter 82 or a transmission filter 83, a conventional large coaxial resonator with a high space factor that has been used in an antenna duplexer can be omitted, thus obtaining an antenna duplexer 80 with a highly reduced size.

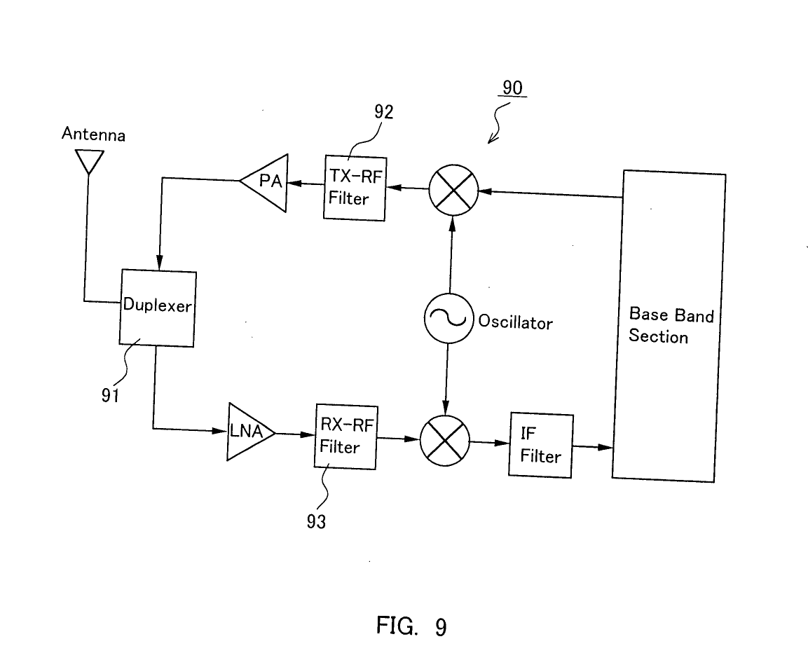

Moreover, when the laminated dielectric filter of the present embodiment is used for one of or all of a duplexer 91 and RF filters 92 and 93 in communication equipment 90 such as portable telephones or the like as shown in FIG. 9, desired characteristics can be obtained in communication equipment with a limited size. Thus, the laminated dielectric filter of the present embodiment also contributes to the size reduction of the communication equipment.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A filter, comprising a plurality of resonators, the resonators being coupled to one another by electromagnetic-field coupling,
wherein non-adjacent resonators of said plurality of resonators are electrically coupled to each other with a series circuit formed of a capacitor and a transmission line.

2. The filter according to claim 1, wherein adjacent resonators of said plurality of resonators are electrically coupled to each other with a series circuit formed of a capacitor and a transmission line.

3. The filter according to claim 1, wherein the plurality of resonators and the transmission line are formed inside a dielectric body.

4. A dielectric filter, comprising:
a plurality of shield electrodes formed on outer faces of a dielectric body;
resonator electrodes formed of at least three front end short-circuit ¼ wavelength transmission lines;
a plurality of first transmission line electrodes, each of which has portions opposing respective portions of two adjacent resonator electrodes included in the resonator electrodes; and
second transmission line electrodes having portions opposing the plurality of first transmission electrodes, respectively,
wherein the resonator electrodes, the plurality of first transmission line electrodes, and the second transmission line electrodes are formed between the plurality of shield electrodes.

5. The dielectric filter according to claim 4, wherein the plurality of shield electrodes are connected to each other, and then are grounded.

6. The dielectric filter according to claim 4, wherein the dielectric filter includes capacitor electrodes formed of the first transmission lines opposing the resonator electrodes on outermost sides, and the capacitor electrodes are connected to side electrodes to form input/output terminals.

7. The dielectric filter according to claim 4, wherein capacitor electrodes are formed of the second transmission lines opposing open ends of the resonator electrodes and are grounded.

8. A laminated dielectric filter, comprising:
a first dielectric layer;
a second dielectric layer;
a third dielectric layer;
a fourth dielectric layer;
a first shield electrode;
a second shield electrode;
resonator electrodes formed of at least three front end short-circuit ¼ wavelength transmission lines;
a plurality of inter-stage coupling capacitor electrodes, each of which is formed of a transmission line having portions opposing respective portions of two adjacent resonator electrodes included in the resonator electrodes; and
bypass electrodes formed of transmission lines having portions opposing the plurality of inter-stage coupling capacitor electrodes, respectively,
wherein the first dielectric layer is laminated above the first shied electrode, the resonator electrodes are formed on an upper surface of the first dielectric layer, the second dielectric layer is laminated above the resonator electrodes, the inter-stage coupling capacitor electrodes are formed on an upper surface of the second dielectric layer, the third dielectric layer is laminated above the inter-stage coupling capacitor electrodes, the bypass electrodes are formed on an upper surface of the third dielectric layer, the fourth dielectric layer is laminated above the bypass electrodes, and the second shield electrode is positioned on an upper surface of the fourth dielectric layer.

9. The laminated dielectric filter according to claim 8, wherein the first shield electrode is provided on an upper surface of a fifth dielectric layer.

10. The laminated dielectric filter according to claim 8, further comprising a sixth dielectric layer laminated above the second shield electrode.

11. The laminated dielectric filter according to claim 8, wherein the first shield electrode and the second shield electrode are connected and then are grounded.

12. The laminated dielectric filter according to claim 8, further comprising capacitor electrodes formed of the transmission lines opposing the resonator electrodes on outermost sides,
wherein the capacitor electrodes are connected to side electrodes to form input/output terminals.

13. The laminated dielectric filter according to claim 8, wherein capacitor electrodes are formed of transmission lines opposing open ends of the resonator electrodes and are grounded.

14. An antenna duplexer, comprising a filter including a plurality of resonators, the resonators being coupled to one another by electromagnetic-field coupling,
wherein non-adjacent resonators of said plurality of resonators are electrically coupled to each other with a series circuit formed of a capacitor and a transmission line, and
the filter is used as one of or both of filters on transmission and reception sides.

15. An antenna duplexer, comprising a dielectric filter including:
a plurality of shield electrodes formed on outer faces of a dielectric body;
resonator electrodes formed of at least three front end short-circuit ¼ wavelength transmission lines;
a plurality of first transmission line electrodes, each of which has portions opposing respective portions of two adjacent resonator electrodes included in the resonator electrodes; and
second transmission line electrodes having portions opposing the plurality of first transmission electrodes, respectively,
wherein the resonator electrodes, the plurality of first transmission line electrodes, and the second transmission line electrodes are formed between the plurality of shield electrodes, and
the dielectric filter is used as one of or both of filters on transmission and reception sides.

16. An antenna duplexer, comprising a laminated dielectric filter including:
a first dielectric layer;
a second dielectric layer;
a third dielectric layer;
a fourth dielectric layer;
a first shield electrode;
a second shield electrode;
resonator electrodes formed of at least three front end short-circuit ¼ wavelength transmission lines;
a plurality of inter-stage coupling capacitor electrodes, each of which is formed of a transmission line having portions opposing respective portions of two adjacent resonator electrodes included in the resonator electrodes; and
bypass electrodes formed of transmission lines having portions opposing the plurality of inter-stage coupling capacitor electrodes, respectively,
wherein the first dielectric layer is laminated above the first shied electrode, the resonator electrodes are formed on an upper surface of the first dielectric layer, the second dielectric layer is laminated above the resonator electrodes, the inter-stage coupling capacitor electrodes are formed on an upper surface of the second dielectric layer, the third dielectric layer is laminated above the inter-stage coupling capacitor electrodes, the bypass electrodes are formed on an upper surface of the third dielectric layer, the fourth dielectric layer is laminated above the bypass electrodes, and the second shield electrode is positioned on an upper surface of the fourth dielectric layer, and
the laminated dielectric filter is used as one of or both of filters on transmission and reception sides.

17. Communication equipment, comprising a filter including a plurality of resonators, the resonators being coupled to one another by electromagnetic-field coupling;
wherein non-adjacent resonators of said plurality of resonators are electrically coupled to each other with a series circuit formed of a capacitor and a transmission line.

18. Communication equipment, comprising a dielectric filter including:
a plurality of shield electrodes formed on outer faces of a dielectric body;
resonator electrodes formed of at least three front end short-circuit ¼ wavelength transmission lines;
a plurality of first transmission line electrodes, each of which has portions opposing respective portions of two adjacent resonator electrodes included in the resonator electrodes; and
second transmission line electrodes having portions opposing the plurality of first transmission electrodes, respectively,
wherein the resonator electrodes, the plurality of first transmission line electrodes, and the second transmission line electrodes are formed between the plurality of shield electrodes.

19. Communication equipment, comprising a laminated dielectric filter including:
a first dielectric layer;
a second dielectric layer;
a third dielectric layer;
a fourth dielectric layer;
a first shield electrode;
a second shield electrode;
resonator electrodes formed of at least three front end short-circuit ¼ wavelength transmission lines;
a plurality of inter-stage coupling capacitor electrodes, each of which is formed of a transmission line having portions opposing respective portions of two adjacent resonator electrodes included in the resonator electrodes; and
bypass electrodes formed of transmission lines having portions opposing the plurality of inter-stage coupling capacitor electrodes, respectively,
wherein the first dielectric layer is laminated above the first shied electrode, the resonator electrodes are formed on an upper surface of the first dielectric layer, the second dielectric layer is laminated above the resonator electrodes, the inter-stage coupling capacitor electrodes are formed on an upper surface of the second dielectric layer, the third dielectric layer is laminated above the inter-stage coupling capacitor electrodes, the bypass electrodes are formed on an upper surface of the third dielectric layer, the fourth dielectric layer is laminated above the bypass electrodes, and the second shield electrode is positioned on an upper surface of the fourth dielectric layer.
